(19) United States
(12) Patent Application Publication
(10) Pub. No.: US 2022/0208963 A1
(43) Pub. Date: Jun. 30, 2022

(54) ESD PROTECTION DEVICE

(71) Applicant: Silergy Semiconductor Technology (Hangzhou) LTD, Hangzhou (CN)

(72) Inventors: Guoyan Zhang, Hangzhou (CN); Gang He, Hangzhou (CN)

(21) Appl. No.: 17/543,948

(22) Filed: Dec. 7, 2021

(30) Foreign Application Priority Data
Dec. 28, 2020 (CN) 202011584197.X

(51) Int. Cl. H01L 29/06; H01L 29/861; H01L 29/40

(52) U.S. Cl. CPC H01L 29/0615; H01L 29/402; H01L 29/861

(57) ABSTRACT

An ESD protection device can include: a base layer; a first well region of a first doping type and extending from an upper surface of the base layer to internal portion of the base layer; a first doped region of a first doping type and located in the first well region and extending from the upper surface of the base layer to internal portion of the base layer; a second doped region of second doping type and extending from the upper surface of the base layer to internal portion of the base layer; a field oxide layer located on the upper surface of the base layer and adjacent to the second doped region; and a field plate extending from the upper surface of the field oxide layer to the first doped region.

### RELATED APPLICATIONS

This application claims the benefit of Chinese Patent Application No. 202011584197.X, filed on Dec. 28, 2020, which is incorporated herein by reference in its entirety.

### FIELD OF THE INVENTION

The present invention generally relates to the field of semiconductor technology, and more particularly to electrostatic discharge (ESD) protection devices.

### BACKGROUND

The damage of static electricity to electronic products has always been a difficult problem, particularly in high-voltage circuit applications. In order not to affect the normal operating performance of the product, the power port of the circuit may need a ESD device having a high holding voltage, in order to prevent the latch-up effect. A diode is an electrostatic discharge (ESD) device commonly used in the industry, but its design in high-voltage applications may have drawbacks, such as a relatively high on-resistance and poor current capability per unit area.

### BRIEF DESCRIPTION OF THE DRAWINGS

FIG. 1 is sectional view of a first example ESD protection device, in accordance with embodiments of the present invention.

FIG. 2 is sectional view of a second example ESD protection device, in accordance with embodiments of the present invention.

FIG. 3 is sectional view of a third example ESD protection device, in accordance with embodiments of the present invention.

FIG. 4 is sectional view of a fourth example ESD protection device, in accordance with embodiments of the present invention.

### DETAILED DESCRIPTION

Reference may now be made in detail to particular embodiments of the invention, examples of which are illustrated in the accompanying drawings. While the invention may be described in conjunction with the preferred embodiments, it may be understood that they are not intended to limit the invention to these embodiments. On the contrary, the invention is intended to cover alternatives, modifications and equivalents that may be included within the spirit and scope of the invention as defined by the appended claims. Furthermore, in the following detailed description of the present invention, numerous specific details are set forth in order to provide a thorough understanding of the present invention. However, it may be readily apparent to one skilled in the art that the present invention may be practiced without these specific details. In other instances, well-known methods, procedures, processes, components, structures, and circuits have not been described in detail so as not to unnecessarily obscure aspects of the present invention.

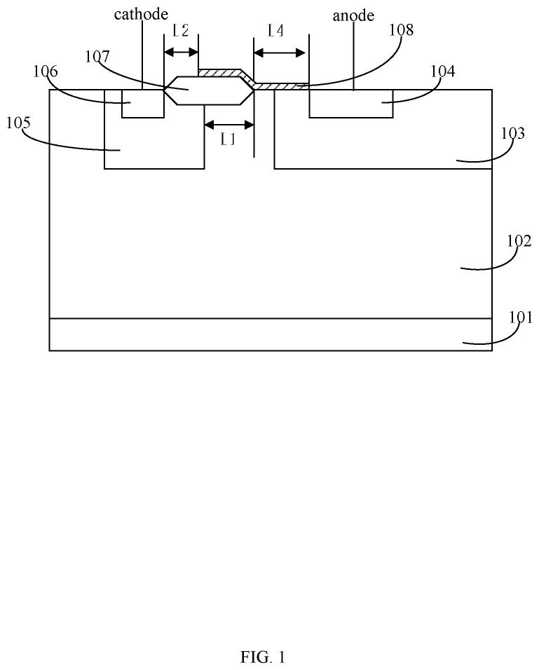

Referring now to FIG. 1, shown is sectional view of a first example electrostatic discharge (ESD) protection device, in accordance with embodiments of the present invention. In this particular example, substrate 101 can be made of silicon, and be of a first doping type. The first doping type is one of N-type and P-type, and a second doping type is the other one of the N-type and the P-type. In this example, a base layer can include substrate 101 and high-voltage well region 102 of the second doping type located in substrate 101. In other examples, the base layer may also include substrate 101 and an epitaxial layer of the second doping type on substrate 101. Alternatively, the base layer may also only include substrate 101.

The ESD protection device can also include well region 103 of the first doping type, doped region 104 of the first doping type, doped region 106 of the second doping type, field oxide layer 107, and field plate 108. For example, well region 103 may extend from an upper surface of high-voltage well region 102 to an internal portion thereof. Also, doped region 104 can be located in well region 103, and may extend from the upper surface of high-voltage well region 102 to an internal portion thereof. Doped region 106 may extend from the upper surface of high-voltage well region 102 to an internal portion thereof. In addition, field oxide layer 107 can be located on an upper surface of the base layer and adjacent to doped region 106. Field oxide layer 107 and doped region 106 can be in contact with each other, or there can be a certain distance therebetween. However, if the distance between field oxide layer 107 and doped region 106 increases, the breakdown voltage of the device can also increase, along with the resistance. In addition, field plate 108 may extend from an upper surface of the field oxide layer to doped region 104.

In this example, field oxide layer 107 may not be in contact with doped region 104. Field plate 108 can include a first part on field oxide layer 107, and a second part on the upper surface of high voltage well region 102. The longer the first part of field plate 108 extends on field oxide layer 107; that is, distance L2 between field plate 108 and doped region 106 changes from the maximum to the minimum, the breakdown voltage of the ESD protection device first decreases and then increases. Field plate 108 and doped region 104 may or may not be in contact. In addition, a thin oxide layer can also be included between field plate 108 and the upper surface of high-voltage well region 102, and the thin oxide layer may be adjacent to field oxide layer 107. For example, field plate 108 can include polysilicon material.

The ESD protection device can also include well region 105 of the second doping type. For example, well region 105 may extend from the upper surface of high-voltage well region 102 to an internal portion thereof, and doped region 106 can be located in well region 105. Well region 105 may be not in contact with well region 103, and a junction depth of well region 103 and a junction depth of well region 105 may be equal. For example, the distance between the side of well region 105 close to well region 103 and the side of field oxide layer 107 close to well region 103 is set to L1. Distance L1 may have a great impact on the device, whereby if distance L1 is too small, the breakdown voltage of the ESD protection device can be reduced, and a relatively large resistance region may appear in the current characteristics. If the distance L1 is too large, the breakdown voltage of the ESD protection device can increase, but the resistance of the conduction region can also increase. Therefore, the distance L1 should be set with an appropriate value, which may generally be selected according to the voltage level of the device.

The distance between field oxide layer 107 and the side of field plate 108 close to the doped region 104 can be set to L4. When distance L4 is too small, the JFET effect may be stronger, which can reduce the current capability. When distance L4 is too large, the resistance can increase, and the area of the ESD protection device that is required can increase. Therefore, distance L4 should be set with an appropriate value, which may generally be selected according to the voltage level of the device. In this example, the ESD protection device can be a diode, doped region 104 can connect to the anode electrode, and doped region 106 can connect to the cathode electrode.

In the ESD protection device of certain embodiments, a field plate can be formed between doped region 104 of the anode electrode and doped region 106 of the cathode electrode, in order to optimize the electric field distribution of the device to increase the breakdown voltage of the device. Under the same breakdown voltage, the cell can be set smaller, in order to increase the current capacity per unit area. In addition, well region 105 can be added at the cathode electrode, in order to reduce the on-resistance of the device. Further, well region 103 and well region 105 may not be in contact with each other, in order to increase the breakdown voltage of the device.

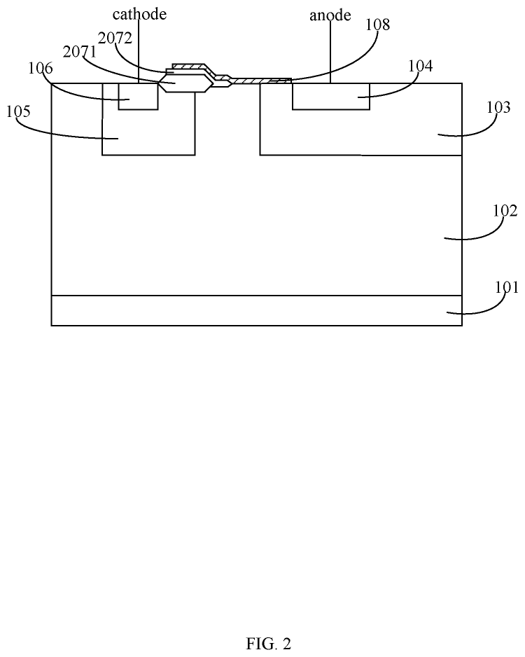

Referring now to FIG. 2, shown is sectional view of a second example ESD protection device, in accordance with embodiments of the present invention. In this particular example, the structure of the field oxide layer is different. For example, the field oxide layer can include oxide layer 2071 and oxide layer 2072. Oxide layer 2071 can be formed on the upper surface of high-voltage well region 102, and oxide layer 2072 may be formed on oxide layer 2071 and the upper surface of high-voltage well region. Oxide layer 2071 and oxide layer 2072 may conformally form a field oxide layer. Oxide layer 2071 can include a first part with uniform thickness, and a second part with uneven thickness at both sides of the first part. The thickness of the second part of oxide layer 2071 may gradually decrease in a direction away from the first part of oxide layer 2071. A side of oxide layer 2072 close to doped region 106 can be aligned with the side of the first part of oxide layer 2071 close to doped region 106.

For example, the field oxide layer may be stepped. Furthermore, in the direction from doped region 106 to doped region 104, the thickness of the field oxide layer formed by oxide layer 2071 and oxide layer 2072 may gradually decrease. In this particular example, the structure of the field oxide layer can make the electric field distribution below the field oxide layer more uniform, thereby substantially avoiding the occurrence of peak electric field, and improving the breakdown voltage of the device.

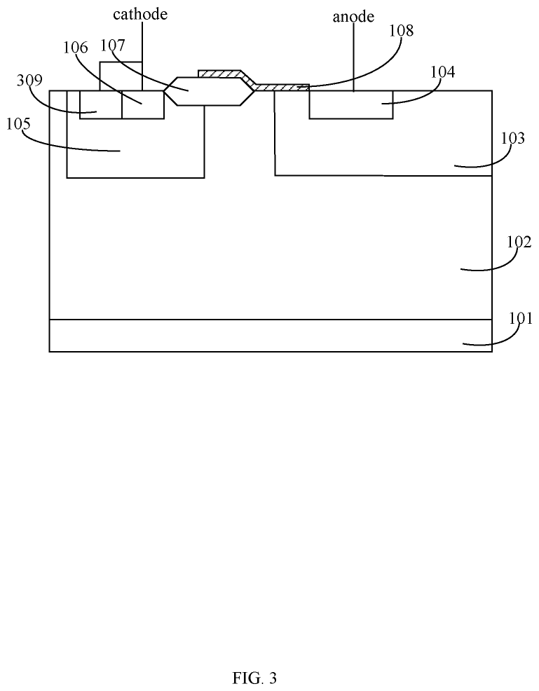

Referring now to FIG. 3, shown is sectional view of a third example ESD protection device, in accordance with embodiments of the present invention. In this particular example, the ESD protection device can include doped region 309 of the first doping type located in well region 105. Doped region 309 can be adjacent to doped region 106, and may be located at the other side opposite to the adjacent side of doped region 106 and field oxide layer 107. In this example, the ESD protection device can be a triode, doped region 104 can connect to an anode electrode, and doped region 106 and doped region 309 can connect to a cathode electrode.

When the cathode electrode is subjected to high-voltage static electricity, an avalanche breakdown can occur between well region 105 of the cathode electrode, high-voltage well region 102 and well region 103 of the anode electrode of the ESD protection device, and the carriers may flow to the cathode electrode. After the diode turns on, the PNP formed by doped region 309, well region 105, high voltage well region 102, well region 103, and doped region 104 can be turned on. As such, the PNP can connect in parallel with the diode, the current capacity can be increased, and the current capacity of the ESD device per unit area may be improved without reducing the holding voltage. In addition, doped region 309 can be arranged on a side away from the first well region to reduce the influence of doped region 309 on the electric field distribution, thereby increasing the breakdown voltage of the device.

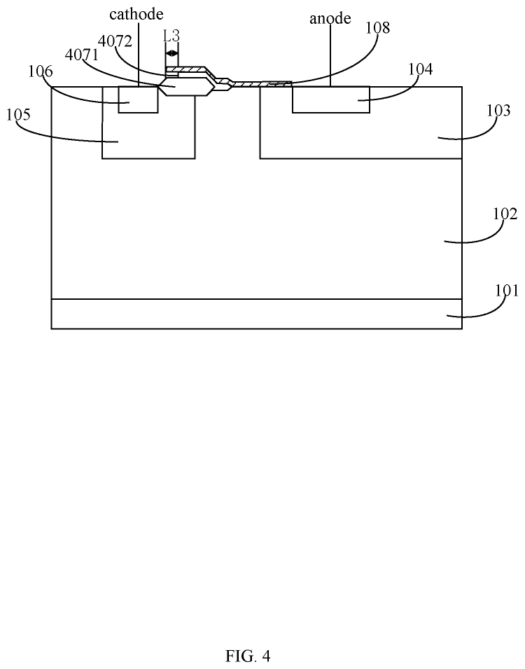

Referring now to FIG. 4, shown is sectional view of a fourth example ESD protection device, in accordance with embodiments of the present invention. In this particular example, the side of oxide layer 4072 close to doped region 106 of the ESD protection device of the fourth example is indented by a certain distance L3 relative to the side of the first part of oxide layer 4071 close to doped region 106. That is, the distance between oxide layer 4072 and doped region 106 can be greater than the distance between the side of the first part of oxide layer 4071 close to the second doped region and second doped region 106.

In this particular example, oxide layer 4071 and oxide layer 4072 may form a step shape on the side close to the doped region 106, in order to reduce the JFET effect, improve the current capability of the ESD device, and increase an electric field peak. This can make the electric field distribution more smooth and increase the breakdown voltage. When the cell size is unchanged, the value of distance L3 can be selected at a position with the optimal electric field and the highest avalanche breakdown voltage. When sufficient breakdown voltage is reached, the ESD area can be the smallest.

The embodiments were chosen and described in order to best explain the principles of the invention and its practical applications, to thereby enable others skilled in the art to best utilize the invention and various embodiments with modifications as are suited to particular use(s) contemplated. It is intended that the scope of the invention be defined by the claims appended hereto and their equivalents.

What is claimed is:

1. An electrostatic discharge (ESD) protection device, comprising:
a) a base layer;
b) a first well region of a first doping type, extending from an upper surface of the base layer to internal portion of the base layer;
c) a first doped region of a first doping type, located in the first well region and extending from the upper surface of the base layer to internal portion of the base layer;
d) a second doped region of second doping type, extending from the upper surface of the base layer to internal portion of the base layer;
e) a field oxide layer located on the upper surface of the base layer and adjacent to the second doped region; and
f) a field plate extending from the upper surface of the field oxide layer to the first doped region.

2. The ESD protection device according to claim 1, wherein the field oxide layer is not in contact with the first doped region.

3. The ESD protection device according to claim 1, further comprising a second well region of the second doping type extending from the upper surface of the base layer to internal portion of the base layer, wherein the second doped region is located in the second well region.

4. The ESD protection device according to claim 1, wherein the field plate comprises a first part on the field oxide layer, and a second part on the upper surface of the base layer.

5. The ESD protection device according to claim 4, further comprising a thin oxide layer located between the field plate and the upper surface of the base layer, wherein the thin oxide layer is adjacent to the field oxide layer.

6. The ESD protection device according to claim 1, wherein the thickness of the field oxide layer decreases along a direction from the second doped region to the first doped region.

7. The ESD protection device according to claim 6, wherein the field oxide layer comprises a first oxide layer on the upper surface of the base layer, and a second oxide layer on the first oxide layer and the upper surface of the base layer.

8. The ESD protection device according to claim 7, wherein the first oxide layer comprises a first part with uniform thickness and a second part with uneven thickness on both sides of the first part.

9. The ESD protection device according to claim 8, wherein a side of the second oxide layer close to the second doped region is aligned with a side of the first part of the first oxide layer close to the second doped region.

10. The ESD protection device according to claim 8, wherein a side of the second oxide layer close to the second doped region is indented relative to a side of the first part of the first oxide layer close to the second doped region.

11. The ESD protection device according to claim 3, wherein the first well region and the second well region are not in contact.

12. The ESD protection device according to claim 1, further comprising a third doped region of the first doping type adjacent to the second doped region, wherein the third doped region is located at the other side opposite to the adjacent side of second doped region and field oxide layer.

13. The ESD protection device according to claim 1, wherein the first doped region is connected to the anode electrode, and the second doped region is connected to the cathode electrode.

14. The ESD protection device according to claim 12, wherein the first doped region is connected to an anode electrode, and the second doped region and the third doped region are connected to a cathode electrode.

15. The ESD protection device according to claim 4, wherein as a distance between the field plate and the second doped region changes from a minimum to a maximum, the breakdown voltage of the device first increases and then decreases.

16. The ESD protection device according to claim 2, wherein the smaller the distance between the side of the field oxide layer close to the first doped region and the side of the field plate close to the first doped region, the smaller the current capability of the device.

17. The ESD protection device according to claim 3, wherein the greater the distance between the side of the second well region close to the first well region and the side of the field oxide layer close to the first well region, the greater the breakdown voltage of the device.

18. The ESD protection device according to claim 1, wherein the base layer comprises a substrate of the first doping type.

19. The ESD protection device according to claim 1, wherein the base layer comprises a substrate of a first doping type and a high-voltage well region of a second doping type located in the substrate, and the first well region is located in the high-voltage well region.

20. The ESD protection device according to claim 1, wherein the field plate is a polysilicon field plate.
